(19) United States
(12) Patent Application Publication
(10) Pub. No.: US 2026/0181825 A1
(43) Pub. Date: Jun. 25, 2026

(54) LIQUID REFILL FIXTURE FOR COOLING SYSTEM

(71) Applicant: META Green Cooling technology Co., Ltd., Taoyuan City (TW)

(72) Inventors: MAO-CHING CHEN, Taipei City (TW); CHIA-CHIEN CHU, Taipei City (TW); REX WU, New Taipei City (TW)

(73) Assignee: META Green Cooling technology Co., Ltd., Taoyuan City (TW)

(21) Appl. No.: 19/192,387

(22) Filed: Apr. 29, 2025

(30) Foreign Application Priority Data
Dec. 19, 2024 (TW) 113149566

(51) Int. Cl. H05K 7/20; B67D 7/02; B67D 7/62; B67D 7/70

(52) U.S. Cl. CPC H05K 7/20272; B67D 7/02; B67D 7/62; B67D 7/70

(57) ABSTRACT

A liquid refill fixture for a cooling system is adapted for refilling the cooling system with a coolant from a coolant tank. The liquid refill fixture for a cooling system includes: a liquid refill pump, having a liquid inlet unit; a pipeline group, including a first pipeline and a second pipeline, the first pipeline adapted to be in communication with the liquid inlet unit of the liquid refill pump and the coolant tank, the second pipeline adapted to be in communication with the first pipeline and the coolant tank; an auxiliary pump, disposed at the second pipeline, adapted to drive a fluid in the second pipeline to flow; and a current controller, electrically connected to the auxiliary pump, for providing the auxiliary pump with operating power and controlling an operating time of the auxiliary pump.

### CROSS-REFERENCE TO RELATED APPLICATION

This non-provisional application claims priority under 35 U.S.C. § 119(a) on Patent Application No(s). 113149566 filed in Taiwan, R.O.C. on Dec. 19, 2024, the entire contents of which are hereby incorporated by reference.

### BACKGROUND OF THE INVENTION

### 1. Field of the Invention

The present disclosure relates to a fluid transporting apparatus, and in particular to a liquid refill fixture for refilling a cooling system with a coolant.

### 2. Description of the Related Art

Along with the improvement of computing performance of electronic apparatuses, cooling distribution units (CDUs) are extensively applied in data centers in order to quickly reduce heat energy produced by electronic computing elements, so as to enhance the operating efficiency and prolong the lifespan of apparatuses.

In general, after a CDU operates for a period of time, the CDU usually has to be periodically refilled with a coolant in order to maintain its performance. To complete the process above, a hose is mostly connected to a liquid refill pump located inside the CDU and a liquid refill tank located outside the CDU, and an interior of the CDU can be refilled with the coolant from the liquid refill tank through the hose by operations of the liquid refill pump, thereby maintaining normal operations of the CDU.

However, one issue often arises in actual operations; although the liquid refill pump can actuate liquid and gas, the liquid refill pump may run idling due to a large amount of air in the hose during its initial start period, such that the coolant cannot be effectively drawn and even lead to overheating and damage of the liquid refill pump.

To solve the issue above, operating staff usually has to manually eliminate the air from within the hose for the time being. For example, the coolant is loaded into another container and poured from a first end of the hose until it overflows a second end of the hose in the liquid refill tank, and then the first end of the hose is connected to the liquid refill pump. Alternatively, the hose is put into a larger container, placed horizontally and completely immersed in the coolant to discharge air from within the pipe. Then, both ends of the hose filled with the coolant therein are respectively connected to the liquid refill pump and the liquid refill tank.

### BRIEF SUMMARY OF THE INVENTION

However, the means of manually eliminating the air from within the hose by operating staff involves complex and time consuming operations, and inevitably results in splashing the coolant on the ground of the ambient environment or around machines. In addition to subsequent cleaning, occurrences of short-circuits of electronic apparatuses or accidents such as slipping or falling of staff also become likely. Moreover, a small amount of air residing in the hose can be input into the CDU only after the liquid refill pump has continued operating for a period of time, and is then discharged to an exterior via an air vent on a top end of the CDU, leading to a certain extent of negative influences on the suction and flow efficiency of the coolant.

In view of the drawbacks of the conventional techniques above, the applicant has dedicated extensive research and development to provide a liquid refill fixture for a cooling system. The liquid refill fixture for a cooling system is capable of automatically achieving an effect of liquid refill without involving manual intervention or intervention of an additional controller. Moreover, most air within a pipeline group can be discharged before entering an interior of the cooling system, so as to enhance suction and flow efficiency of the coolant.

To achieve the above and other objectives, the present disclosure provides a liquid refill fixture for a cooling system and adapted for refilling the cooling system with a coolant from a coolant tank. The liquid refill fixture for a cooling system includes: a liquid refill pump, having a liquid inlet unit; a pipeline group, including a first pipeline and a second pipeline, the first pipeline adapted to be in communication with the liquid inlet unit of the liquid refill pump and the coolant tank, the second pipeline adapted to be in communication with the first pipeline and the coolant tank; an auxiliary pump, disposed at the second pipeline, adapted to drive a fluid in the second pipeline to flow; and a current controller, electrically connected to the auxiliary pump, for providing the auxiliary pump with operating power and controlling an operating time of the auxiliary pump.

In the liquid refill fixture for a cooling system above, the current controller may be a relay.

In the liquid refill fixture for a cooling system above, the current controller may be a time relay or a delay relay.

The liquid refill fixture for a cooling system above may further include another current controller. The another current controller is electrically connected to the liquid refill pump, and controls activation and deactivation of the liquid refill pump.

In the liquid refill fixture for a cooling system above, the liquid refill pump may further include a three-way fitting. The three-way fitting has three ports, which are respectively connected to the liquid inlet unit, the first pipeline and the second pipeline.

In the liquid refill fixture for a cooling system above, the pipeline group may further include a third pipeline. One end of the third pipeline is in communication with a liquid outlet unit of the liquid refill pump, and the other end is adapted to be in communication with the interior of the cooling system. The liquid refill pump may further include a check valve. The check valve may be connected to the liquid outlet unit and one end of the third pipeline, or may be disposed between both ends of the third pipeline.

In the liquid refill fixture for a cooling system above, the auxiliary pump has a fluid inlet and a fluid outlet, and the second pipeline may include a first section and a second section. One end of the first section of the second pipeline may be in communication with the fluid inlet, the other end is adapted to be in communication with the coolant tank, and the second section of the second pipeline may be in communication with the fluid outlet and the first pipeline.

The liquid refill fixture for a cooling system above may further include a housing in which all of the liquid refill pump, the auxiliary pump and the current controller may be disposed.

In the liquid refill fixture for a cooling system above, the liquid refill pump or the auxiliary pump may be a diaphragm pump, an air-operated pump, a self-priming pump, or a vortex pump.

Thus, the liquid refill fixture for a cooling system of the present disclosure is capable of achieving an effect of automatic coolant refill without involving manually eliminating air from within a pipeline group by operating staff, thus enhancing efficiency and convenience for coolant refill as well as preventing the occurrence of splashing the coolant on the ground of the ambient environment or around machines. Moreover, most air within a pipeline group can be guided into the coolant tank and be discharged before input along with the coolant to the interior of the cooling system, so as to enhance suction and flow efficiency of the coolant. More particularly, the liquid refill fixture of the present disclosure provides the auxiliary pump with operating power by the current controller, and can thus meet different operating time requirements of the auxiliary pump by means of selecting current controllers with different capacities without involving manual intervention or intervention of an additional controller, hence being extremely convenient in use, effectively reducing apparatus costs and complexities, providing high control stability with minimal malfunctions, and reducing maintenance costs.

### BRIEF DESCRIPTION OF THE DRAWINGS

FIG. 1 is a perspective schematic diagram according to an embodiment of the present disclosure, with a sealing lid of a housing omitted.

FIG. 2 is a partial enlarged perspective schematic diagram according to an embodiment of the present disclosure, with a housing omitted.

FIG. 3 is a simple structural schematic diagram according to an embodiment of the present disclosure, wherein the arrow indicates a direction of flow of a coolant when the auxiliary pump is in operation.

FIG. 4 is a simple structural schematic diagram according to an embodiment of the present disclosure, wherein the arrow indicates a direction of flow of a coolant when the liquid refill pump is in operation.

### DETAILED DESCRIPTION OF THE INVENTION

To facilitate understanding of the objectives, characteristics and effects of the present disclosure, embodiments together with the attached drawings for the detailed description of the present disclosure are provided below.

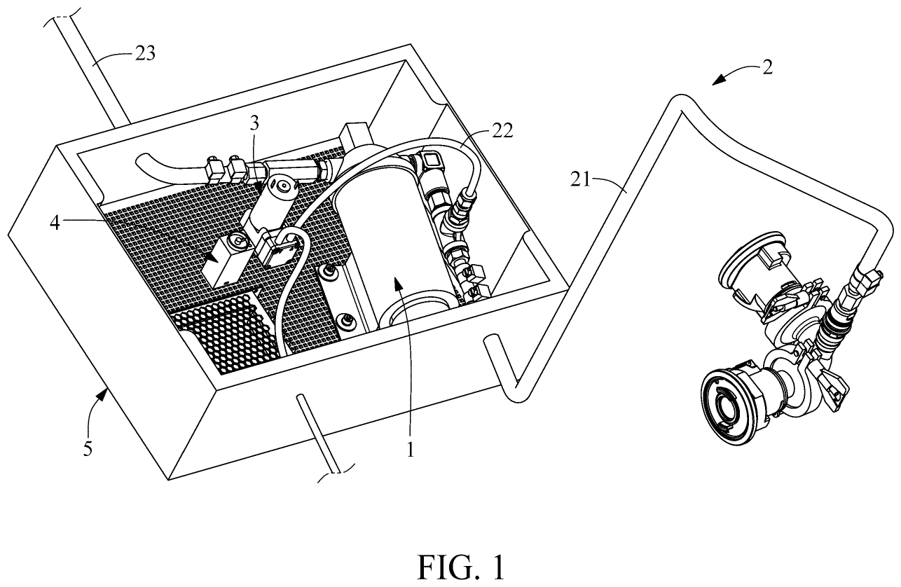

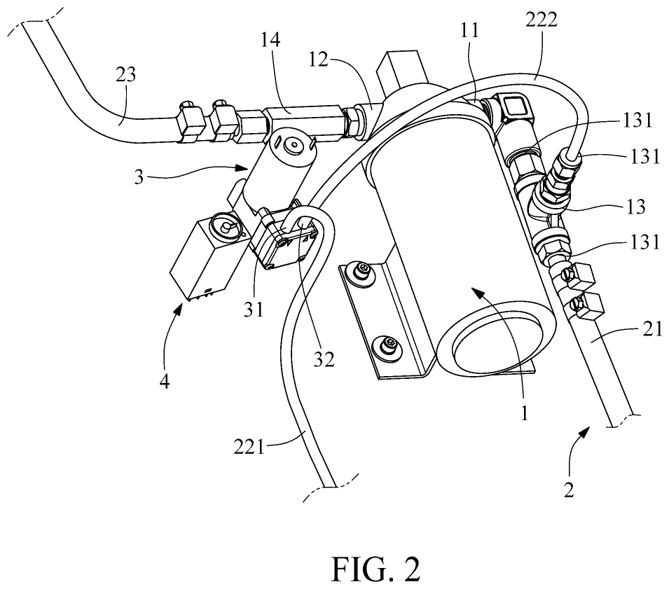

Refer to FIG. 1 and FIG. 2 showing a liquid refill fixture for a cooling system according to a preferred embodiment of the present disclosure. The liquid refill fixture for a cooling system includes a liquid refill pump 1, a pipeline group 2, an auxiliary pump 3 and a current controller 4. The pipeline group 2 is in communication with the liquid refill pump 1 and the auxiliary pump 3. The pipeline group 2 is adapted to be in communication with a coolant tank (not shown). The current controller 4 is electrically connected to the auxiliary pump 3.

The liquid refill pump 1 has a liquid inlet unit 11 and a liquid outlet unit 12. When the liquid refill pump 1 is in operation, a fluid can be driven and be guided into the liquid refill pump 1 via the liquid inlet unit 11, and be discharged from the liquid outlet unit 12. In one embodiment of the present disclosure, the liquid refill pump 1 can be implemented by a diaphragm pump, an air-operated pump, a self-priming pump, a vortex pump or a positive displacement pump, and is adapted to drive a gas, a liquid or a mixture thereof to flow. Preferably, the liquid refill pump 1 is a diaphragm pump, which is unlikely to burn or damage even under operating conditions where a liquid cannot be pumped and a gas is pumped for an extended period of time.

The pipeline group 2 includes a first pipeline 21 and a second pipeline 22. The first pipeline 21 is adapted to be in communication with the liquid inlet unit 11 of the liquid refill pump 1 and the coolant tank, and the second pipeline 22 is adapted to be in communication with the first pipeline 21 and the coolant tank.

The auxiliary pump 3 is disposed at the second pipeline 22, and is adapted to drive a fluid in the second pipeline 22 to flow. In one embodiment of the present disclosure, the auxiliary pump 3 has a fluid inlet 31 and a fluid outlet 32, and the second pipeline 22 may include a first section 221 and a second section 222. One end of the first section 221 of the second pipeline 22 is in communication with the fluid inlet 31 of the auxiliary pump 3, and the other end is adapted to be in communication with the coolant tank. The second section 222 of the second pipeline 22 is in communication with the fluid outlet 32 of the auxiliary pump 3 and the first pipeline 21. Moreover, the auxiliary pump 3 may be a pump in a form same as or different from the liquid refill pump 1, and such is not specifically defined by the present disclosure.

The current controller 4 is electrically connected to the auxiliary pump 3, and is for providing the auxiliary pump 3 with operating power and controlling an operating time of the auxiliary pump 3. The current controller 4 may be, for example, a relay.

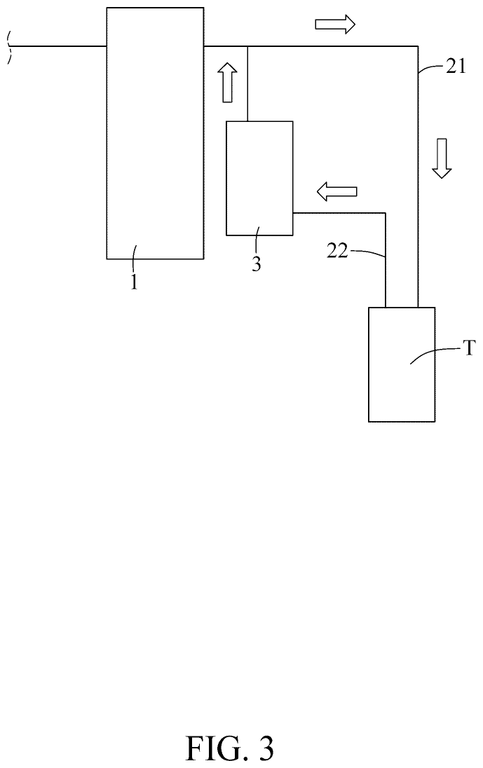

The liquid refill fixture of this embodiment can refill a cooling system (for example but not limited to, a CDU) with a coolant. Referring to FIG. 1 and FIG. 3, for implementing coolant refill, the current controller 4 may be first controlled to provide the auxiliary pump 3 with operating power, such that the auxiliary pump 3 starts operating to drive the fluid in the second pipeline 22 to flow. At this point in time, the auxiliary pump 3 draws the coolant from a coolant tank T, and causes the coolant to pass through the second pipeline 22, be input to the first pipeline 21 and then return into the coolant tank T. With the flow of at least one round of circulation, most air in the first pipeline 21 can be guided into the coolant tank T, and the first pipeline 21 can be filled with the coolant or contains only a small amount of air.

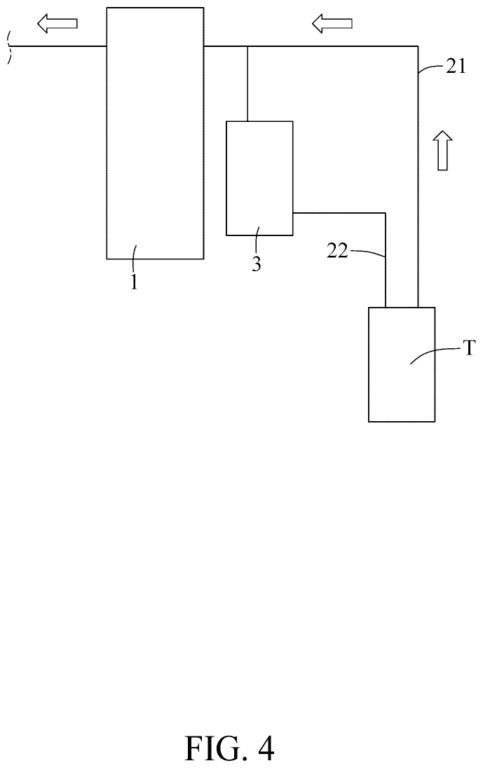

Further referring to FIG. 1 and FIG. 4, after the auxiliary pump 3 operates for a predetermined time (for example, 10 s), the current controller 4 stops providing the auxiliary pump 3 with operating power such that the auxiliary pump 3 stops operating. Next, the liquid refill pump 1 is activated to ensure that the liquid refill pump 1 smoothly draws the coolant from the coolant tank T through the first pipeline 21 and inputs the coolant to an interior of the cooling system, so as to smoothly complete the coolant refill.

Accordingly, the liquid refill fixture of this embodiment is capable of achieving an effect of automatic coolant refill without involving manually eliminating air from within the pipeline group 2 by operating staff, thus enhancing efficiency and convenience for coolant refill as well as preventing the occurrence of splashing the coolant on the ground of the ambient environment or around machines. Moreover, most air within the pipeline group 2 can be guided into the coolant tank and be discharged before input along with the coolant to the interior of the cooling system, so as to enhance suction and flow efficiency of the coolant.

More particularly, the liquid refill fixture of this embodiment provides the auxiliary pump 3 with operating power by the current controller 4, and can thus meet different operating time requirements of the auxiliary pump 3 by means of selecting current controllers 4 with different capacities without involving manual intervention or intervention of an additional controller, hence being extremely convenient in use, effectively reducing apparatus costs and complexities, providing high control stability with minimal malfunctions, and reducing maintenance costs.

In addition to the embodiment above, in one embodiment of the present disclosure, the current controller 4 may be, for example, a time relay or a delay relay. Thus, this embodiment can control an on/off state of a circuit according to a set time delay, so as to adjust the delay time according to requirements. That is, the operating time of the auxiliary pump 3 is effectively controlled by the current controller 4, and the activation of the liquid refill pump 1 is controlled according to a predetermined time after the auxiliary pump 3 is stopped. In other words, the operation of the auxiliary pump 3 may be controlled by an adjustable relay, so that the operating time can be set according to requirements without involving an additional controller, hence reducing apparatus costs and simplifying control settings.

It should be noted that, the operation of the liquid refill pump 1 usually needs to be activated and deactivated by a control system. In one embodiment of the present disclosure, the liquid refill fixture may further include another current controller 4. The another current controller 4 is electrically connected to the liquid refill pump 1, so that the activation and deactivation of the liquid refill pump 1 can be controlled by the another current controller 4. Thus, after the auxiliary pump 3 stops operating, the liquid refill pump 1 can be automatically activated by the another current controller 4, and the respective operating times of the liquid refill pump 1 and the auxiliary pump 3 can be set according to different requirements. Alternatively, in other possible embodiments, other types of controllers (for example, a PLC or an MCU) may also be used to control the operation of the liquid refill pump 1.

Referring to FIG. 2, in addition to the embodiments above, in one embodiment of the present disclosure, the liquid refill pump 1 may further include a three-way fitting 13. The three-way fitting 13 has three ports 131, which are respectively connected to the liquid inlet unit 11, the first pipeline 21 and the second pipeline 22. Thus, in addition to enhancing the convenience and efficiency of assembly of the pipeline group 2 by the three-way fitting 13, the liquid refill fixture of this embodiment can further locate a position at which the second pipeline 22 communicates with the first pipeline 21 to be close to the liquid refill pump 1 as possible, so as to increase the amount of air that can be discharged from within the first pipeline 21 when the auxiliary pump 3 is in operation, hence further reducing the amount of air residing in the first pipeline 21 and enabling the first pipeline 21 to be almost filled with the coolant.

Moreover, in one embodiment of the present disclosure, the pipeline group 2 further includes at third pipeline 23. One end of the third pipeline 23 is in communication with the liquid outlet unit 12 of the liquid refill pump 1, and the other end is adapted to be in communication with the interior of the cooling system. The liquid refill pump 1 may further include a check valve 14. The check valve 14 is connected to the liquid outlet unit 12 and one end of the third pipeline 23, or is disposed between both ends of the third pipeline 23. Thus, the check valve 14 can ensure that the coolant is transported and flows only to the interior of the cooling system instead of back flowing to the liquid refill pump 1.

Again referring to FIG. 1, the liquid refill fixture of this embodiment may further include a housing 5. Components such as the liquid refill pump 1, the auxiliary pump 3 and the current controller 4 may be integrated and arranged in the housing 5 for ease of sale and installation. Moreover, these components are protected by the housing 5 to prevent these components from damage caused by collisions during transportation or installation processes, as well as more readily installing a control circuit within the housing 5 to achieve dustproof and moistureproof functions. Moreover, the form of the housing 5 is not specifically defined in the present disclosure, and is thus not limited to that disclosed in the drawing of this embodiment.

The present disclosure is described by way of the preferred embodiments above. A person skilled in the art should understand that, the embodiments are merely for illustrating the present disclosure and are not to be construed as limitations to the scope of the present disclosure. It should be noted that all equivalent changes, replacements and substitutions made to the embodiments are encompassed within the scope of the present disclosure. Therefore, the legal protection for the present disclosure should be defined by the appended claims.

What is claimed is:

1. A liquid refill fixture for a cooling system, adapted to refill the cooling system with a
coolant from a coolant tank, the liquid refill fixture for a cooling system comprising:
a liquid refill pump, having a liquid inlet unit;
a pipeline group, comprising a first pipeline and a second pipeline, the first pipeline adapted to be in communication with the liquid inlet unit of the liquid refill pump and the coolant tank, and the second pipeline adapted to be in communication with the first pipeline and the coolant tank;
an auxiliary pump, disposed at the second pipeline, adapted to drive a fluid in the second pipeline to flow; and
a current controller, electrically connected to the auxiliary pump, for providing the auxiliary pump with operating power and controlling an operating time of the auxiliary pump.

2. The liquid refill fixture for a cooling system according to claim 1, wherein the current controller is a relay.

3. The liquid refill fixture for a cooling system according to claim 2, wherein the current controller is a time relay or a delay relay.

4. The liquid refill fixture for a cooling system according to claim 3, further comprising:
another current controller, electrically connected to the liquid refill pump, controlling activation and deactivation of the liquid refill pump.

5. The liquid refill fixture for a cooling system according to claim 1, wherein the liquid refill pump further comprises a three-way fitting, which has three ports respectively connected to the liquid inlet unit, the first pipeline and the second pipeline.

6. The liquid refill fixture for a cooling system according to claim 1, wherein the pipeline group further comprises a third pipeline; one end of the third pipeline is in communication with a liquid outlet unit of the liquid refill pump, and one other end is adapted to be in communication with the interior of the cooling system; the liquid refill pump further comprises a check valve; the check valve is connected to the liquid outlet unit and one end of the third pipeline, or is disposed between both ends of the third pipeline.

7. The liquid refill fixture for a cooling system according to claim 1, wherein the auxiliary pump has a fluid inlet and a fluid outlet, and the second pipeline comprises a first section and a second section; one end of the first section of the second pipeline is in communication with the fluid inlet, one other end is adapted to be in communication with the coolant tank, and the second section of the second pipeline is in communication with the fluid outlet and the first pipeline.

8. The liquid refill fixture for a cooling system according to claim 1, further comprising:
a housing, in which all of the liquid refill pump, the auxiliary pump and the current controller are disposed.

9. The liquid refill fixture for a cooling system according to claim 1, wherein the liquid refill pump or the auxiliary pump is a diaphragm pump, an air-operated pump, a self-priming pump, or a vortex pump.
